(19) United States
(12) Patent Application Publication
(10) Pub. No.: US 2011/0164380 A1
(43) Pub. Date: Jul. 7, 2011

(54) CIRCUIT BOARD ASSEMBLY

(75) Inventors: Jeng-Da WU, Tu-Cheng (TW); Chih-Hang CHAO, Tu-Cheng (TW); Zhi-Ping WU, Shenzhen City (CN)

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/750,927

(22) Filed: Mar. 31, 2010

(30) Foreign Application Priority Data
Jan. 4, 2010 (CN) 201010300028.9

(51) Int. Cl. H05K 7/20

(52) U.S. Cl. 361/688

(57) ABSTRACT

A circuit board assembly is provided, includes a circuit board having a first side and a second side opposite to the first side. A chip is connected to the first side of the circuit board. A first heat dissipating device is located on the first side of the circuit board. The chip is located between the first heat dissipating device and the first side of the circuit board. A second heat dissipating device abuts the second side of the circuit board, and the second heat dissipating device are secured to the first heat dissipating device to clamp the circuit board and the chip.

### BACKGROUND

1. Technical Field

The present disclosure relates to circuit board assemblies, more particularly, to a circuit board assembly configured to minimize or prevent damage to a chip on a circuit board from impact.

2. Description of Related Art

A semiconductor chip is usually mounted on a printed circuit board by jointing solder spots of the semiconductor chip to the printed circuit board via lead made tin balls. The tin ball resists damage, because of good capability of lead for absorbing shock. However, due to the dangers of lead polluting environment and damaging people's health, nonleaded tin balls are now common in the process of mounting a semiconductor chip to a printed circuit board. However, because of poor capability of non-leaded tin balls to resist shock, they are damaged easily when the printed circuit board suffers an impact. This will affect signal transmission between the semiconductor chip and the printed circuit board.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of a circuit board assembly in accordance with an embodiment.

FIG. 2 is an assembled view of FIG. 1.

FIG. 3 is a front view of an embodiment of the circuit board assembly when mounted in a computer enclosure.

FIG. 4 is an enlarged view of IV in FIG. 3.

FIG. 5 is a diagram of an acceleration curve used for simulating the impact applied on an embodiment of the circuit board assembly.

FIG. 6 is a diagram of curve to illustrate stress on points A and D of a tin ball of a circuit board assembly according to the prior art.

FIG. 7 is a diagram of curve to illustrate stress on points A and D of the circuit board assembly in FIG. 4.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

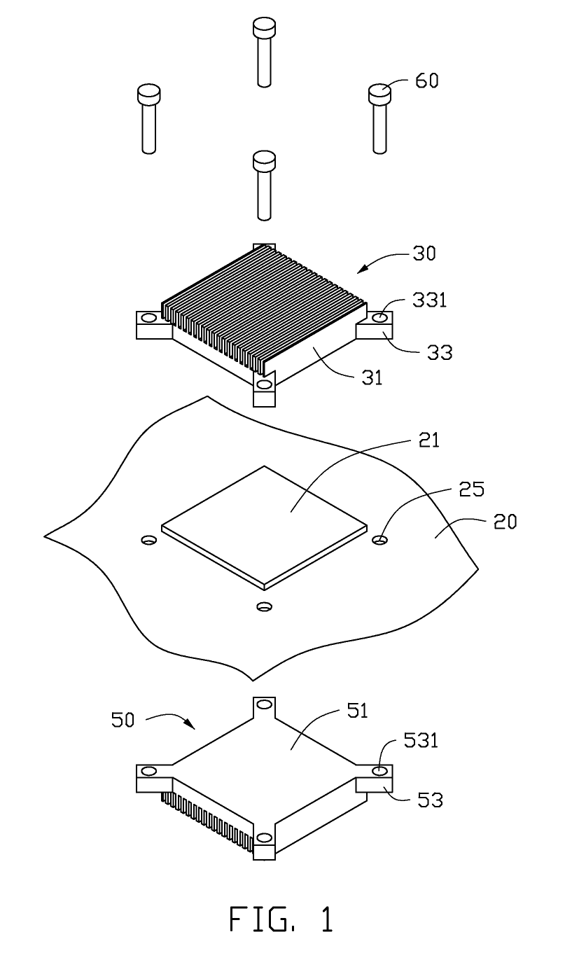

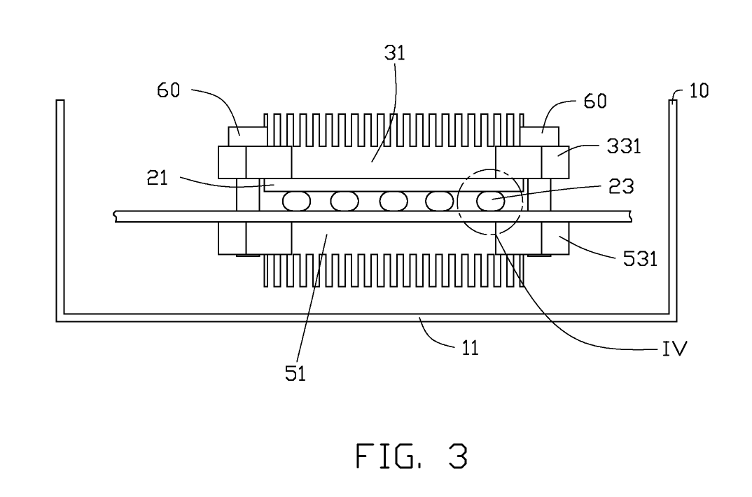

Referring to FIGS. 1 to 3, a circuit board assembly in accordance with one embodiment includes a circuit board 20 mounted in a computer enclosure 10, a first heat dissipating device 30, and a second heat dissipating device 50. The computer enclosure 10 includes a bottom wall 11 (shown in FIG. 3).

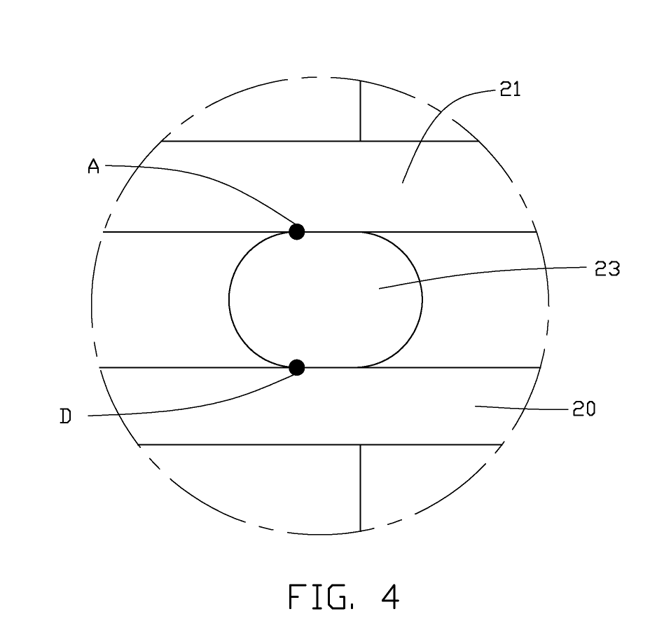

A chip 21, such as a CPU, is disposed on a first side of the circuit board 20. The chip 21 connects to the circuit board 20 via a plurality of tin balls 23 (shown in FIG. 4) connected to circuit board 20. A plurality of through holes 25 is defined in the circuit board 20 around the chip 21.

The first heat dissipating device 30 includes a first heat dissipating body 31. The first heat dissipating body 31 can be substantially rectangular. A plurality of first securing seats 33 radiantly extend from the corners of the first heat dissipating body 31. Each first securing seat 33 defines a first mounting hole 331. The first mounting holes 331 corresponds to the through holes 25 in the circuit board 20.

The second heat dissipating device 50 includes a second heat dissipating body 51. The second heat dissipating body 51 can be substantially rectangular. A plurality of second securing seats 53 radiantly extend from the corners of the first heat dissipating body 51. Each second securing seat 53 defines a second mounting hole 531. The second mounting holes 531 correspond to the through holes 25 in the circuit board 20.

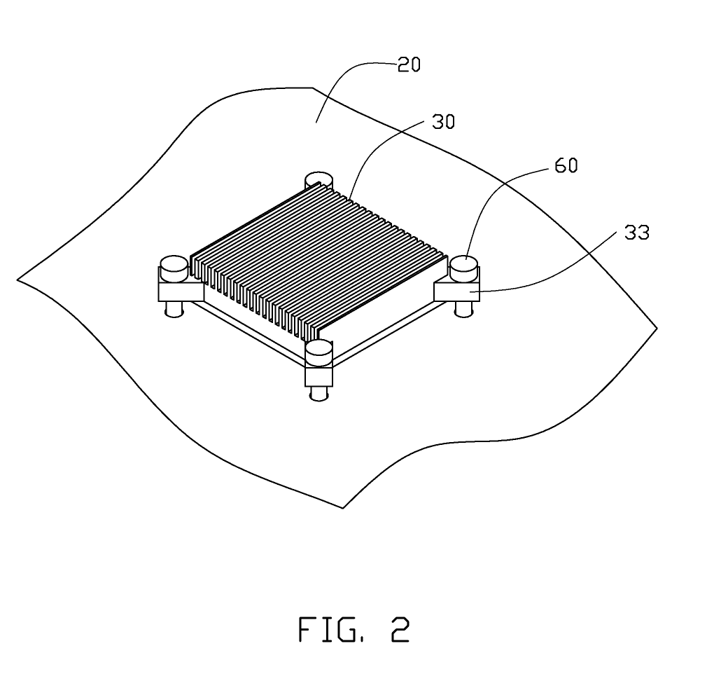

Referring to FIGS. 2 and 3, in assembly, the first heat dissipating body 31 of the first heat dissipating device 30 abuts against the chip 21 on the circuit board 20. The second heat dissipating body 51 of the second heat dissipating device 50 abuts against a second side of the circuit board 20. The first mounting holes 331 and the second mounting holes 531 align with the through holes 25 in the circuit board 20. A plurality of fasteners 60 extend through the first mounting holes 331, the through holes 25, and the second mounting holes 531, to secure the first heat dissipating device 30 and the second heat dissipating device 50 to the circuit board 20. The circuit board 20 and the chip 21 are clamped between the first heat dissipating device 30 and the second heat dissipating device 50. Then, the circuit board 20 with the first heat dissipating device 30 and the second heat dissipating device 50 are secured to the bottom wall 11 of the computer enclosure 10. Distance between the circuit board 20 and the bottom wall 11 is greater than a thickness of the second heat dissipating device 50.

When the computer enclosure 10 suffers an impact, the first principal stress applied on the tin balls 23 between the circuit board 20 and the chip 21 will decrease, since the circuit board 20 and the chip 20 are clamped between the first heat dissipating device 30 and the second heat dissipating device 50. Thus, the tin balls 23 will be protected from being damaged.

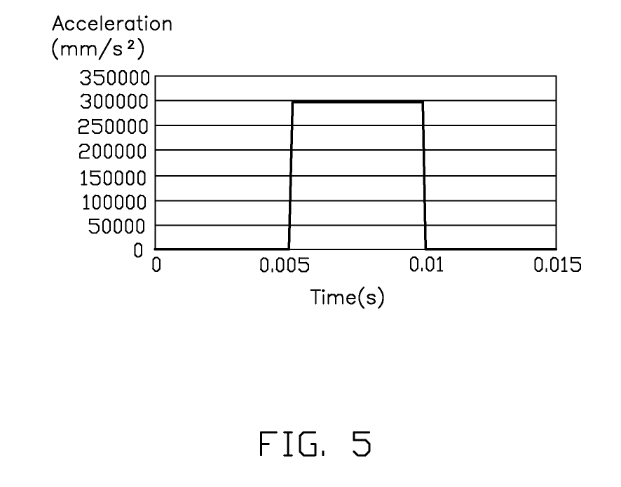

Referring to FIGS. 4 to 7, a software LS-DYNA is used for simulating the first principal stress applied on the tin balls 23 when the circuit board 20 suffers an impact. Generally, when the circuit board assembly suffers an impact, joints between the circuit board 20 and the tin balls 23 and joints between the chip 21 and the tin balls 23 suffer the greater stress. Accordingly, during the simulation, only the first principal stresses, applied to a point A of one tin ball 23 at a joint between the circuit board 20 and the tin ball 23 and a point D at a joint between the chip 21 and the tin balls 23, are shown. An acceleration curve (shown in FIG. 5) is used for simulating the impact applied on the circuit board 20.

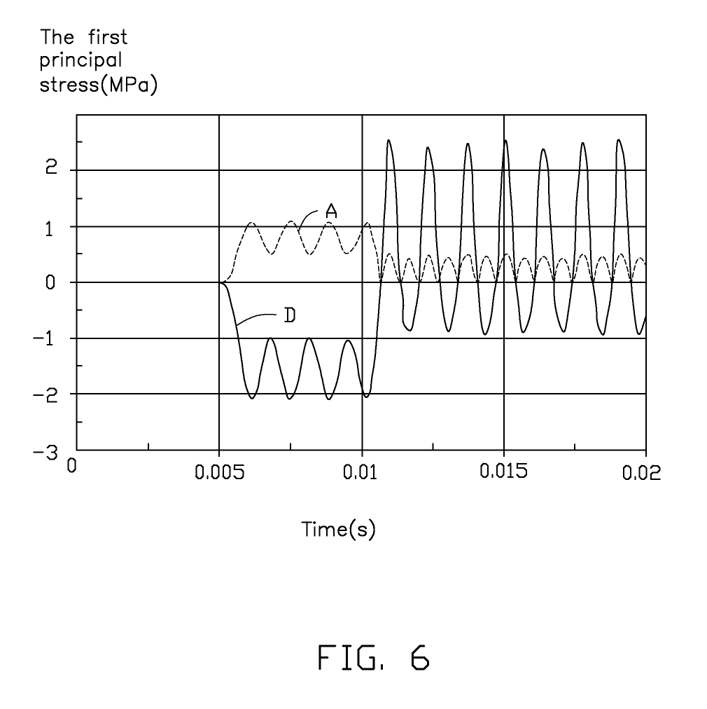

FIG. 6 shows the first principal stress distribution of the points A and D of a conventional circuit board assembly The broken line shows the first principal stress distribution of the point A at a joint between the chip and a tin ball. The solid line shows the first principal stress distribution of the point D at a joint between the tin ball and the circuit board. When the first principal stress value is positive, the tin balls suffer tensile stress. When the first principal stress value is negative, the tin balls suffer compressive stress. Generally, the tin balls will not be damaged when suffering compressive stress, but may easily damage when suffering large tensile stress. Referring to FIG. 6, the first principal stress values on the point A are positive. Most of the stress values on the point D are positive and greater than 2 MPa. Therefore, the points A and D, suffer great tensile stress and are easily damage.

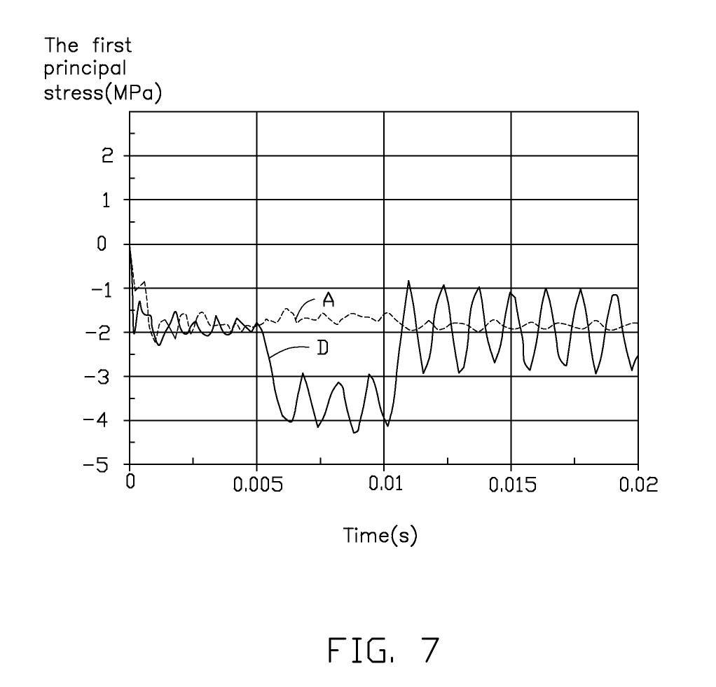

FIG. 7 shows the first principal stress distribution of the points A and D of the circuit board assembly in accordance with one embodiment. The first principal stress values of the points A and D of the tin balls 23 are negative. That is, when the circuit board assembly suffers impact, the points A and D of the tin balls 23 only suffers compressive stress, and the stress value is small enough to yield and may not damage the tin balls.

In one embodiment, the circuit board 20 and the chip 21 are clamped between the first heat dissipating device 30 and the second heat dissipating device 50, to apply compressive stress to the tin balls 23. When the circuit board 20 suffers an impact, the compressive stress may counteract the tensile stress applied on the tin balls 23 thereby effectively preventing the tin balls 23 from damage.

It is to be understood, however, that even though numerous characteristics and advantages of the embodiments have been set forth in the foregoing description, together with details of the structure and function of the present disclosure, the disclosure is illustrative only, and changes may be made in detail, especially in matters of shape, size, and arrangement of parts within the principles of the embodiments to the full extent indicated by the broad general meaning of the terms in which the appended claims are expressed.

What is claimed is:

1. A circuit board assembly, comprising:
a circuit board having a first side and a second side, opposite to the first side;
a chip connected to the first side of the circuit board;
a first heat dissipating device located on the first side of the circuit board, and the chip is located between the first heat dissipating device and the first side of the circuit board; and
a second heat dissipating device abutting the second side of the circuit board, and the second heat dissipating device being secured to the first heat dissipating device to clamp the circuit board and the chip.

2. The circuit board assembly of claim 1, wherein a plurality of through holes are defined in the circuit board, and a plurality of fasteners extend through the plurality of through holes to secure the second heat dissipating device to the first heat dissipating device.

3. The circuit board assembly of claim 2, wherein the first heat dissipating device comprises a first heat dissipating body abutting the chip, a plurality of first securing seats protrudes from the first heat dissipating body, and each first securing seat defines a first mounting hole; and the plurality of fasteners extend through the first mounting holes to secure the first heat dissipating device.

4. The circuit board assembly of claim 3, wherein the plurality of first securing seats extend from corners of the first heat dissipating device.

5. The circuit board assembly of claim 3, wherein the second heat dissipating device comprises a second heat dissipating body abutting the second side of the circuit board, and each second securing seat defines a second mounting hole; and the fasteners extend through the first mounting holes and the second mounting holes to secure the second heat dissipating device.

6. The circuit board assembly of claim 5, wherein the second securing seats radiately extend from the corners of the second heat dissipating device.

7. A circuit board assembly, comprising:
a circuit board;
a chip disposed on a first side of the circuit board;
a first heat dissipating device secured to the circuit board and abutting the chip;
a second heat dissipating device located on a second side of the circuit board; and
a plurality of fasteners, the plurality of fasteners securing the first heat dissipating device and the second heat dissipating device to the circuit board, wherein the first heat dissipating device and the second heat dissipating device clamp the circuit board under pressure.

8. The circuit board assembly of claim 7, wherein a plurality of through holes are defined in the circuit board, and the fasteners extend through the plurality of through holes to secure the second heat dissipating device to the first heat dissipating device.

9. The circuit board assembly of claim 8, wherein the first heat dissipating device comprises a first heat dissipating body abutting the chip, a plurality of first securing seats protrude from the first heat dissipating body, and each first securing seat defines a first mounting hole; and the plurality of fasteners extends through the first mounting holes.

10. The circuit board assembly of claim 9, wherein the plurality of first securing seats extends from corners of the first heat dissipating device.

11. The circuit board assembly of claim 9, wherein the second heat dissipating device comprises a second heat dissipating body that abuts the second side of the circuit board, and each second securing seat defines a second mounting hole; and the fasteners extend through the first mounting holes and the second mounting holes.

12. The circuit board assembly of claim 11, wherein the second securing seats radiately extend from the corners of the second heat dissipating device.
